(19) United States
(12) Patent Application Publication
(10) Pub. No.: US 2025/0203850 A1
(43) Pub. Date: Jun. 19, 2025

(54) SEMICONDUCTOR DEVICE

(71) Applicant: Samsung Electronics Co., Ltd., Suwon-si (KR)

(72) Inventors: TAE JIN KIM, Suwon-si (KR); TAEJIN PARK, Suwon-si (KR); CHEONBAE KIM, Suwon-si (KR); HYEON-KYU LEE, Suwon-si (KR); SUNG SOO YIM, Suwon-si (KR)

(21) Appl. No.: 18/768,133

(22) Filed: Jul. 10, 2024

(30) Foreign Application Priority Data
Dec. 19, 2023 (KR) 10-2023-0185721

(51) Int. Cl. H10B 12/00

(52) U.S. Cl. CPC H10B 12/482; H10B 12/315; H10B 12/50

(57) ABSTRACT

A semiconductor device may include a bit line structure extending in a first direction, a channel layer on the bit line structure, a gate structure on the bit line structure and extending in a second direction crossing the first direction, and a data storage structure electrically connected to the channel layer. The bit line structure may include a first side surface and a second side surface that are parallel to the first direction, and the channel layer may include a first side surface and a second side surface that are parallel to the first direction. The first side surface of the bit line structure may be coplanar with the first side surface of the channel layer, and the second side surface of the bit line structure may be coplanar with the second side surface of the channel layer.

### CROSS-REFERENCE TO RELATED APPLICATIONS

This U.S. non-provisional patent application claims priority under 35 U.S.C. § 119 to Korean Patent Application No. 10-2023-0185721, filed on Dec. 19, 2023, in the Korean Intellectual Property Office, the entire contents of which are hereby incorporated by reference.

### BACKGROUND OF THE INVENTION

The present disclosure relates to a semiconductor device, and in particular, to a semiconductor device including a bit line structure.

Due to their small-sized, multifunctional, and/or low-cost characteristics, semiconductor devices are being esteemed as important elements in the electronics industry. Semiconductor devices can be classified into a semiconductor memory device for storing data, a semiconductor logic device for processing data, and a hybrid semiconductor device including both of memory and logic elements.

With the recent trend of high speed and low power consumption of electronic devices, semiconductor devices in the electronic devices may also be required to have high operating speeds and/or low operating voltages, and in order to satisfy this requirement, it can be beneficial to increase an integration density of a semiconductor device. However, as the integration density of the semiconductor device increases, the semiconductor device may suffer from deteriorated electrical characteristics and low production yield. Accordingly, many studies are being conducted to improve the electrical characteristics and production yield of the semiconductor device.

### SUMMARY OF THE INVENTION

An embodiment of the inventive concept provides a semiconductor device with improved electric characteristics and an increased integration density.

According to an embodiment of the inventive concept, a semiconductor device may include a bit line structure extending in a first direction, a channel layer on the bit line structure, a gate structure on the bit line structure and extending in a second direction crossing the first direction, and a data storage structure electrically connected to the channel layer. The bit line structure may include a first side surface and a second side surface that are parallel to the first direction, and the channel layer may include a first side surface and a second side surface that are parallel to the first direction. The first side surface of the bit line structure may be coplanar with the first side surface of the channel layer, and the second side surface of the bit line structure may be coplanar with the second side surface of the channel layer.

According to an embodiment of the inventive concept, a semiconductor device may include a gate connection transistor, a shield layer at a level higher than the gate connection transistor, a shield insulating layer on the shield layer, a gate connection contact extending in the shield insulating layer, bit line structures on a top surface of the shield insulating layer, a gate connection pad on the top surface of the shield insulating layer and a top surface of the gate connection contact, and gate structures on the bit line structures. One of the gate structures may be electrically connected to the gate connection transistor through the gate connection pad and the gate connection contact.

According to an embodiment of the inventive concept, a semiconductor device may include a substrate, a bit line connection transistor on the substrate, a gate connection transistor on the substrate, a peripheral circuit insulating layer on the substrate, a shield layer on the peripheral circuit insulating layer, a shield insulating layer on the shield layer, a bit line structure on the shield insulating layer, a gate connection pad on the shield insulating layer, a first gate connection contact extending in the shield insulating layer, a bit line connection contact extending in the shield insulating layer, a gate structure on the bit line structure, a channel layer on the bit line structure, a pad structure on the channel layer, and a data storage structure electrically connected to the pad structure. The gate structure may be electrically connected to the gate connection transistor through the gate connection pad and the first gate connection contact, and the bit line structure may be electrically connected to the bit line connection transistor through the bit line connection contact.

According to an embodiment of the inventive concept, a method of fabricating a semiconductor device may include forming a shield layer, forming a shield insulating layer on the shield layer, forming a preliminary bit line structure and material layer on the shield insulating layer, patterning the material layer and the preliminary bit line structure to form a preliminary channel layer and a bit line structure, respectively, and patterning the preliminary channel layer to form channel layers.

### BRIEF DESCRIPTION OF THE DRAWINGS

FIG. 1 is a block diagram illustrating a semiconductor device according to an embodiment of the inventive concept.

FIGS. 2 and 3 are perspective views schematically illustrating a semiconductor device according to an embodiment of the inventive concept.

FIG. 4A is a plan view illustrating a semiconductor device according to an embodiment of the inventive concept.

FIG. 4B is a sectional view taken along a line A-A′ of FIG. 4A.

FIG. 4C is a sectional view taken along a line B-B′ of FIG. 4A.

FIG. 4D is an enlarged sectional view of a portion ‘E’ of FIG. 4B.

FIGS. 5A, 5B, 6A, 6B, 7A, 7B, 8A, 8B, and 9 are sectional views illustrating a method of fabricating a semiconductor device according to an embodiment of the inventive concept.

FIGS. 10A and 10B are sectional views illustrating a method of fabricating a semiconductor device according to an embodiment of the inventive concept.

FIGS. 11A and 11B are sectional views illustrating a semiconductor device according to an embodiment of the inventive concept.

FIGS. 12A and 12B are sectional views illustrating a method of fabricating a semiconductor device according to an embodiment of the inventive concept.

### DETAILED DESCRIPTION

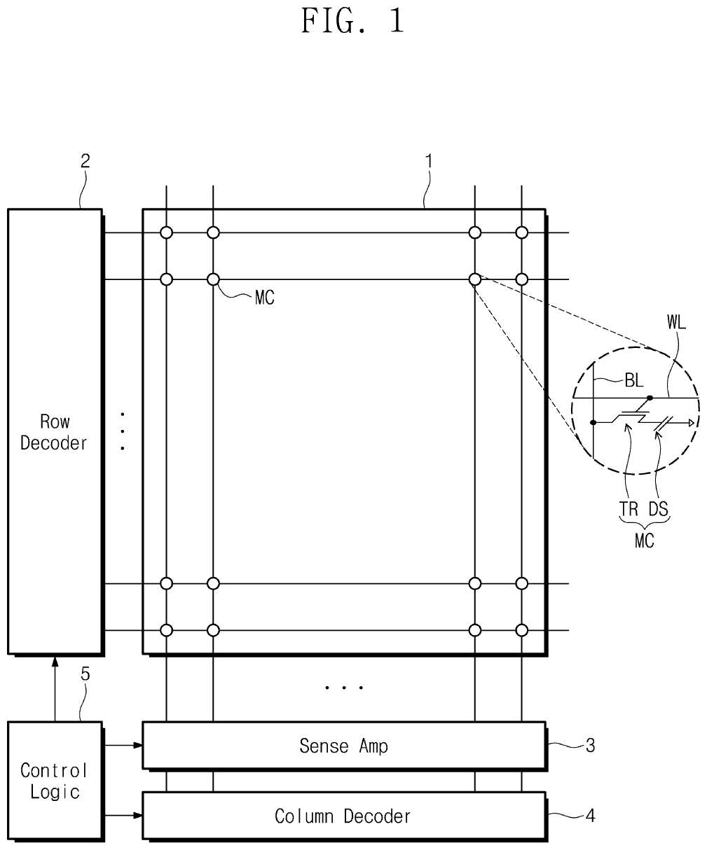

FIG. 1 is a block diagram illustrating a semiconductor device according to an embodiment of the inventive concept.

Referring to FIG. 1, a semiconductor device may include a memory cell array 1, a row decoder 2, a sense amplifier 3, a column decoder 4, and a control logic 5.

The memory cell array 1 may include a plurality of memory cells MC, which are two- or three-dimensionally arranged. Each of the memory cells MC may be provided between and connected to a word line WL and a bit line BL, which are provided to cross each other.

Each of the memory cells MC may include a selection element TR and a data storage device DS. The selection element TR and the data storing element DS may be electrically connected to each other. The selection element TR may be connected to both of the word and bit lines WL and BL. In other words, the selection element TR may be provided at an intersection of the word and bit lines WL and BL.

The selection element TR may include a field effect transistor. The data storing element DS may include a capacitor, a magnetic tunnel junction pattern, or a variable resistor. As an example, the selection element TR may be a transistor whose gate, source, and drain terminals are connected to the word line WL, the bit line BL, and the data storage device DS, respectively.

The row decoder 2 may be configured to decode address information, which is input from the outside (i.e., from outside of the row decoder 2 and/or the semiconductor device), and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside (e.g., from the external device), and to select one of the bit lines BL, based on the decoded address information.

The control logic 5 may generate control signals, which are used to control an operation of writing or reading data to or from the memory cell array 1.

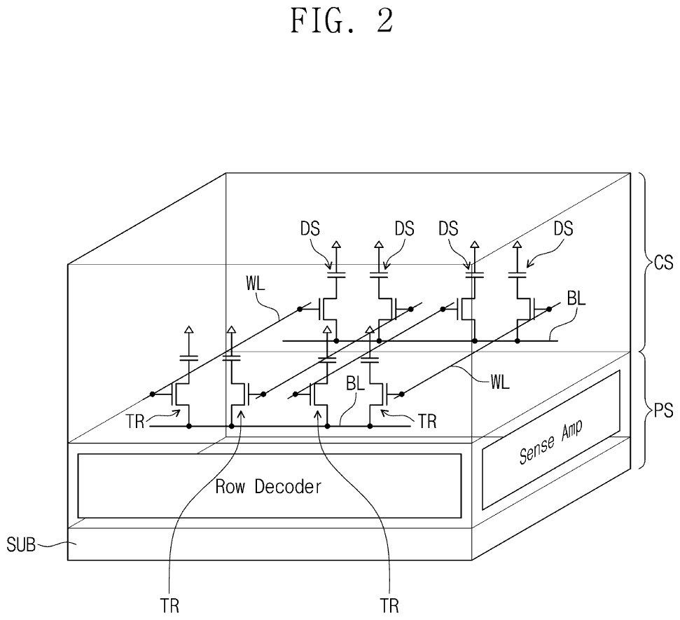

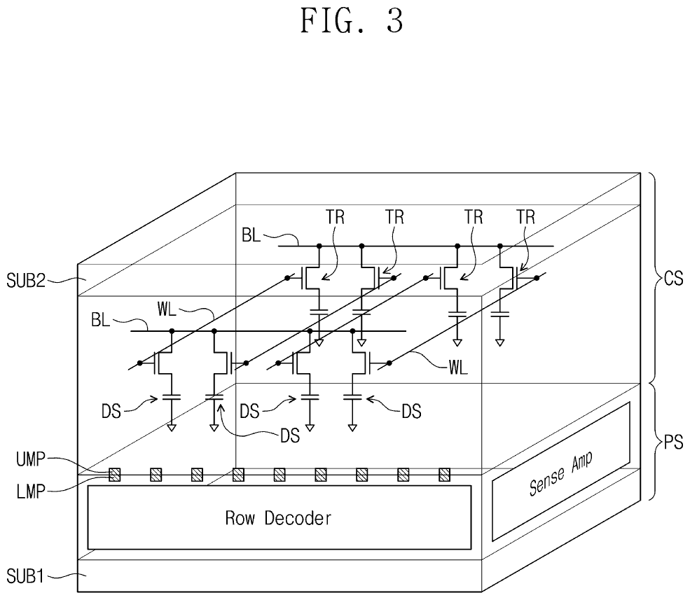

FIGS. 2 and 3 are perspective views schematically illustrating a semiconductor device according to an embodiment of the inventive concept.

Referring to FIGS. 2 and 3, the semiconductor device may include a peripheral circuit structure PS and a cell array structure CS, which is connected to the peripheral circuit structure PS.

The peripheral circuit structure PS may include core and peripheral circuits, which are formed on a substrate SUB. The core and peripheral circuits may include the row and column decoders 2 and 4, the sense amplifier 3, and the control logic 5 described with reference to FIG. 1.

The cell array structure CS may include the memory cell array 1 of FIG. 1, in which the memory cells MC of FIG. 1 are two- or three-dimensionally arranged. Each of the memory cells MC may include the selection element TR and the data storage device DS, as described above.

In an embodiment, the selection element TR of each of the memory cells MC of FIG. 1 may include a vertical channel transistor (VCT). The vertical channel transistor may have a channel region whose lengthwise direction is substantially normal to a top surface of the substrate SUB. The data storage device DS of each of the memory cells MC of FIG. 1 may include a capacitor.

In the embodiment of FIG. 2, the peripheral circuit structure PS may be provided on the substrate SUB, and the cell array structure CS may be provided on the peripheral circuit structure PS.

In the embodiment of FIG. 3, the peripheral circuit structure PS may be provided on a first substrate SUB1, and the cell array structure CS may be provided on a second substrate SUB2 that is disposed to face the first substrate SUB1.

First metal pads LMP may be provided in the uppermost portion of the peripheral circuit structure PS. The first metal pads LMP may be electrically connected to the core and peripheral circuits (e.g., 2, 3, 4, and 5 of FIG. 1).

Second metal pads UMP may be provided in the lowermost portion of the cell array structure CS. The second metal pads UMP may be electrically connected to the memory cell array 1 of FIG. 1. The second metal pads UMP may be directly bonded to (i.e., in direct contact with) the first metal pads LMP of the peripheral circuit structure PS.

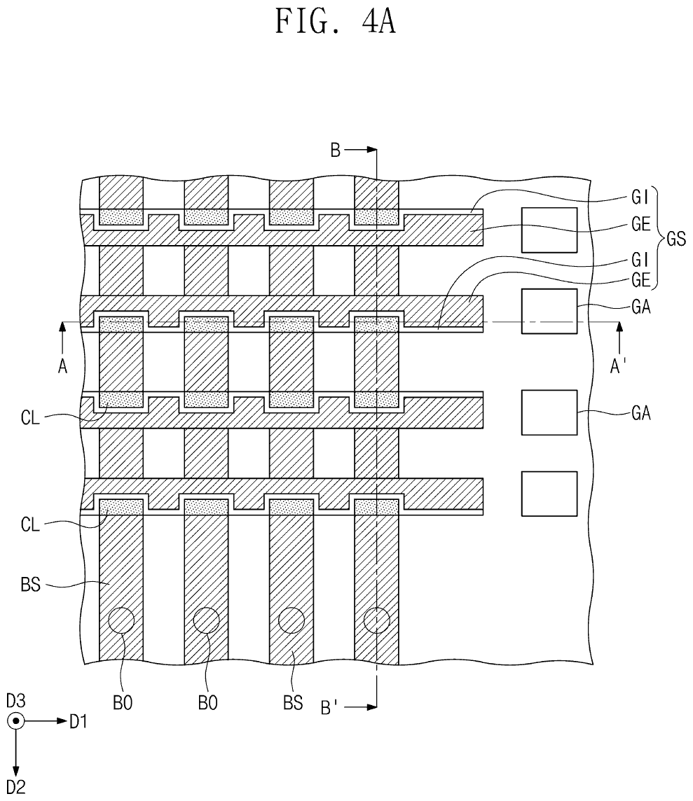

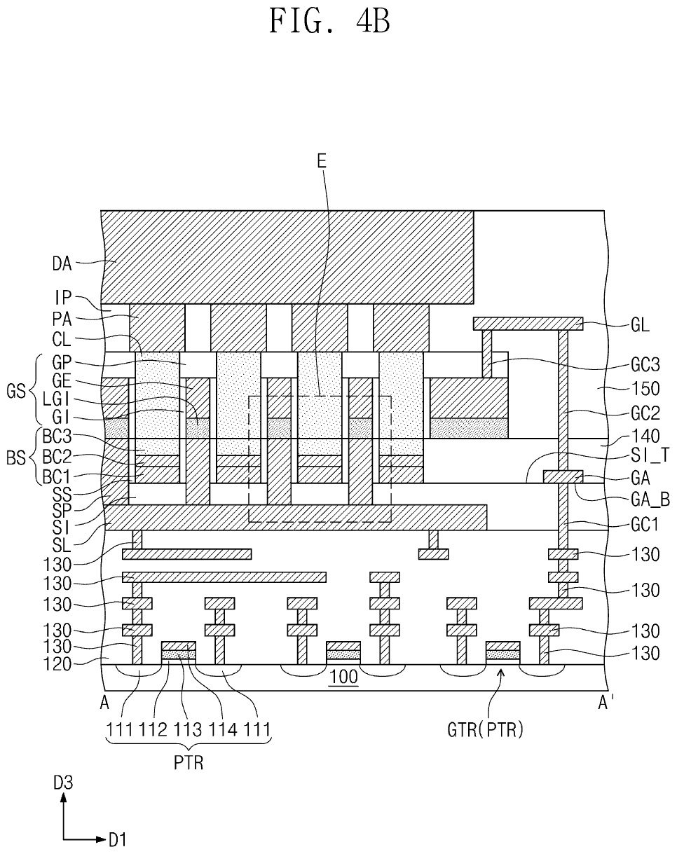

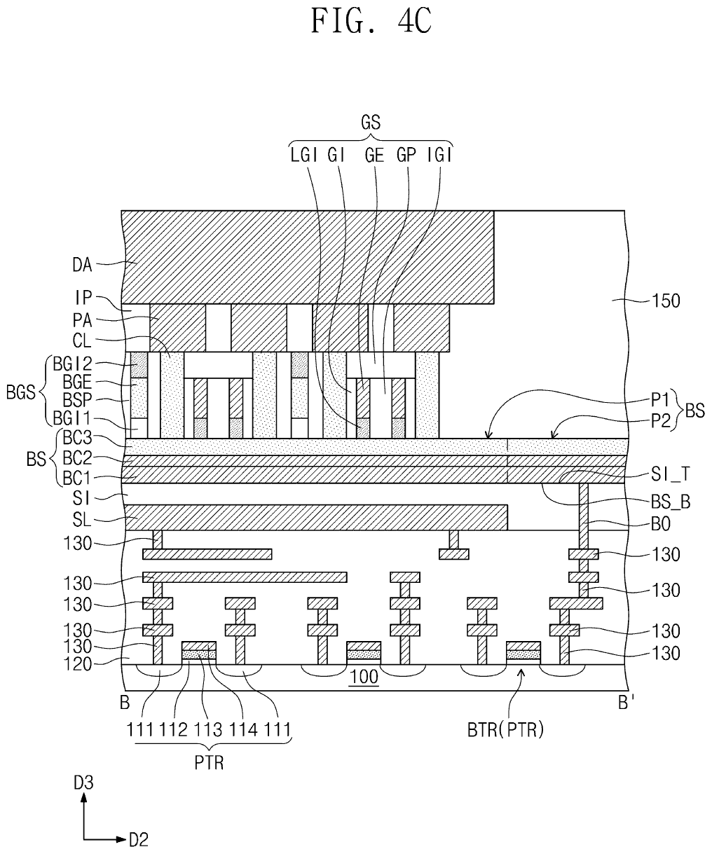

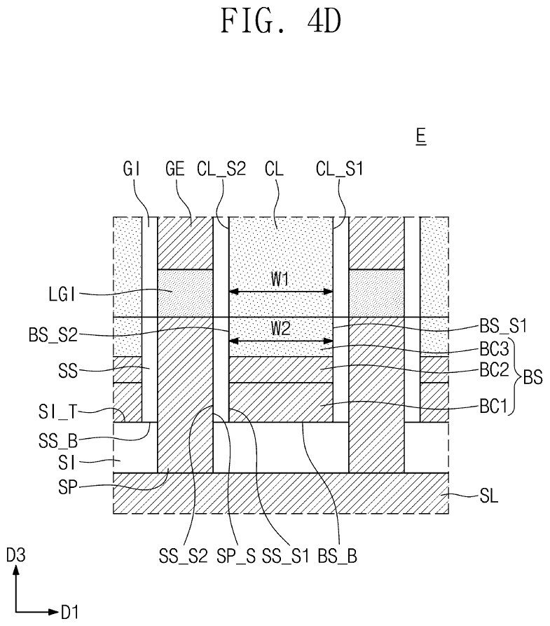

FIG. 4A is a plan view illustrating a semiconductor device according to an embodiment of the inventive concept. FIG. 4B is a sectional view taken along a line A-A′ of FIG. 4A. FIG. 4C is a sectional view taken along a line B-B′ of FIG. 4A. FIG. 4D is an enlarged sectional view of a portion ‘E’ of FIG. 4B.

Referring to FIGS. 4A to 4D, a substrate 100 may be provided. The substrate 100 may be a semiconductor substrate, an insulating substrate, a silicon-on-insulator (SOI) substrate, or a germanium-on-insulator (GOI) substrate.

The substrate 100 may be a plate-shaped structure that extends parallel to a plane defined by a first direction D1 and a second direction D2. The first and second directions D1 and D2 may not be parallel to each other. As an example, the first and second directions D1 and D2 may be horizontal directions that are orthogonal to each other. Moreover, depending on the context, the first and second directions D1 and D2 may be referred to herein as “second” and “first” directions, respectively, such as when the direction D2 is mentioned before the direction D1.

Peripheral transistors PTR may be provided on the substrate 100. Each of the peripheral transistors PTR may include impurity regions 111, a peripheral gate insulating layer 112, a first peripheral gate electrode layer 113, and a second peripheral gate electrode layer 114. The impurity regions 111 may be formed by doping the substrate 100 with impurities. The peripheral gate insulating layer 112 may include an insulating material. The first and second peripheral gate electrode layers 113 and 114 may include a conductive material. In an embodiment, the first peripheral gate electrode layer 113 may be formed of or include poly silicon, and the second peripheral gate electrode layer 114 may be formed of or include a metallic material.

The peripheral transistors PTR may include a gate connection transistor GTR and a bit line connection transistor BTR. The gate connection transistor GTR may be electrically connected to a gate structure GS, which will be described below. In an embodiment, the gate connection transistor GTR may be a transistor, which is used as a part of a sub-word line driver. The bit line connection transistor BTR may be electrically connected to a bit line structure BS, which will be described below. In an embodiment, the bit line connection transistor BTR may be a transistor, which is used as a part of a sense amplifier.

A peripheral circuit insulating layer 120 may be provided on the substrate 100. The peripheral circuit insulating layer 120 may cover the peripheral transistors PTR. The peripheral circuit insulating layer 120 may include an insulating material. In an embodiment, the peripheral circuit insulating layer 120 may have a multi-layer structure including a plurality of insulating layers.

Peripheral conductive structures 130 may be provided in the peripheral circuit insulating layer 120. At least one of the peripheral conductive structures 130 may be electrically connected to the peripheral transistor PTR. The peripheral conductive structures 130 may include a conductive material. The peripheral conductive structures 130 may be formed of or include at least one of, for example, conductive contacts, conductive lines, or conductive pads.

A shield layer SL may be provided on the peripheral circuit insulating layer 120. The shield layer SL may include a conductive material. A shield insulating layer SI may be provided on the shield layer SL. The shield insulating layer SI may include an insulating material. In an embodiment, the shield insulating layer SI may have a multi-layer structure including a plurality of insulating layers.

The shield insulating layer SI may be in contact with a top surface of the shield layer SL, a side surface of the shield layer SL, and a top surface of the peripheral circuit insulating layer 120. The shield layer SL and the shield insulating layer SI may be disposed at a level that is higher than the substrate 100 and the peripheral transistors PTR.

A first gate connection contact GC1 may be provided in (e.g., to pass through) the shield insulating layer SI. A first gate connection contact GC1 may extend in a third direction D3 through the shield insulating layer SI. The third direction D3 may not be parallel to the first and second directions D1 and D2. As an example, the third direction D3 may be a vertical direction that is orthogonal to the first and second directions D1 and D2. The first gate connection contact GC1 may include a conductive material.

A bottom surface of the first gate connection contact GC1 may be in contact with a top surface of the peripheral conductive structure 130. A level of the bottom surface of the first gate connection contact GC1 may be lower, in the third direction D3, than a level of a bottom surface of the shield layer SL and a level of a bottom surface of the shield insulating layer SI. Accordingly, a distance from the bottom surface of the first gate connection contact GC1 to the substrate 100 in the third direction D3 may be smaller than a distance from the bottom surface of the shield layer SL to the substrate 100 in the third direction D3 and a distance from the bottom surface of the shield insulating layer SI to the substrate 100 in the third direction D3. A top surface of the first gate connection contact GC1 may be coplanar with a top surface SI_T of the shield insulating layer SI. The top surface of the first gate connection contact GC1 may thus be located at the same level as the top surface SI_T of the shield insulating layer SI.

A gate connection pad GA may be provided on the first gate connection contact GC1 and the shield insulating layer SI. The gate connection pad GA may be disposed at a level that is higher, in the third direction D3, than the shield insulating layer SI. A bottom surface GA_B of the gate connection pad GA may be in contact with the top surface SI_T of the shield insulating layer SI and the top surface of the first gate connection contact GC1. A level of a top surface of the gate connection pad GA may be lower, in the third direction D3, than a level of a top surface of the bit line structure BS, which will be described below. The gate connection pad GA may include a conductive material.

The gate connection pad GA and the first gate connection contact GC1 may be electrically connected to the gate connection transistor GTR through the peripheral conductive structures 130.

A bit line connection contact BO may be provided in (e.g., to pass through) the shield insulating layer SI. The bit line connection contact BO may extend in the third direction D3 through the shield insulating layer SI. The bit line connection contact BO may include a conductive material.

A bottom surface of the bit line connection contact BO may be in contact with the top surface of the peripheral conductive structure 130. A level of the bottom surface of the bit line connection contact BO may be lower, in the third direction D3, than a level of the bottom surface of the shield layer SL and a level of the bottom surface of the shield insulating layer SI. A top surface of the bit line connection contact BO may be coplanar with the top surface SI_T of the shield insulating layer SI.

The bit line connection contact BO may be electrically connected to the bit line connection transistor BTR through the peripheral conductive structures 130. The bit line connection contact BO may be disposed between the bit line connection transistor BTR and the bit line structure BS.

The bit line structures BS may be provided on the shield insulating layer SI. The bit line structures BS may extend (e.g., extend longitudinally) in the second direction D2. The bit line structures BS may be disposed to be spaced apart from each other in the first direction D1.

Each bit line structure BS may include a first portion P1, which overlaps the shield layer SL in the third direction D3, and a second portion P2, which does not overlap the shield layer SL in the third direction D3. The second portion P2 of the bit line structure BS may be in contact with the bit line connection contact BO. A length of the bit line structure BS in the second direction D2 may be larger than a length of the shield layer SL in the second direction D2.

A bottom surface BS_B of the bit line structure BS may be coplanar with the bottom surface GA_B of the gate connection pad GA. The bottom surface BS_B of the bit line structure BS may be in contact with the top surface SI_T of the shield insulating layer SI and the top surface of the bit line connection contact BO. The bit line structure BS may be electrically connected to the bit line connection transistor BTR through the bit line connection contact BO and the peripheral conductive structures 130. The level of the top surface of the bit line structure BS may be higher, in the third direction D3, than the level of the top surface of the gate connection pad GA.

Each of the bit line structures BS may include a first bit line layer BC1 on the shield insulating layer SI, a second bit line layer BC2 on the first bit line layer BC1, and a third bit line layer BC3 on the second bit line layer BC2. The third bit line layer BC3 may include a conductive material different from the first and second bit line layers BC1 and BC2. In an embodiment, the third bit line layer BC3 may be formed of or include poly silicon, and the first and second bit line layers BC1 and BC2 may be formed of or include a metallic material.

The number of the bit line layers BC1, BC2, and BC3, which are included in the bit line structure BS, is not limited to the illustrated example. In an embodiment, the number of the bit line layers BC1, BC2, and BC3, which are included in the bit line structure BS, may be less than or equal to two or may be greater than or equal to four.

Shield patterns SP may be provided on the shield layer SL. The shield patterns SP may extend in the second direction D2. The shield patterns SP may be disposed to be spaced apart from each other in the first direction D1. The shield pattern SP may be disposed between two bit line structures BS, which are adjacent to each other in the first direction D1. A bottom surface of the shield pattern SP may be in contact with the top surface of the shield layer SL. The shield pattern SP may extend in (e.g., to pass through) the shield insulating layer SI. The shield pattern SP may include a conductive material.

Shield spacers SS may be provided on the shield insulating layer SI. The shield spacers SS may extend in the second direction D2. The shield spacers SS may be disposed to be spaced apart from each other in the first direction D1. Two shield spacers SS may be disposed between two bit line structures BS, which are adjacent to each other in the first direction D1. The shield pattern SP may be disposed between two shield spacers SS, which are spaced apart from each other in the first direction D1. In an embodiment, the two shield spacers SS may be provided on opposite side surfaces of the shield pattern SP.

The shield spacer SS may be disposed between, in the first direction D1, the bit line structure BS and the shield pattern SP. The shield pattern SP may be spaced apart from the bit line structure BS by the shield spacer SS. A bottom surface SS_B of the shield spacer SS may be in contact with the top surface SI_T of the shield insulating layer SI. A level of the bottom surface SS_B of the shield spacer SS may be higher, in the third direction D3, than a level of the bottom surface of the shield pattern SP. The shield spacer SS may include an insulating material.

A first interlayer insulating layer 140 may be provided on the shield insulating layer SI. The gate connection pad GA may be disposed in the first interlayer insulating layer 140. The first interlayer insulating layer 140 may be provided to enclose the gate connection pad GA. The first interlayer insulating layer 140 may be in contact with a side surface of the bit line structure BS and a side surface of the gate connection pad GA. The first interlayer insulating layer 140 may include an insulating material. In an embodiment, the first interlayer insulating layer 140 may have a multi-layer structure including a plurality of insulating layers.

Channel layers CL may be provided. A plurality of channel layers CL may be provided on one bit line structure BS. The channel layers CL, which are provided on one bit line structure BS, may be arranged to be spaced apart from each other in the second direction D2. The channel layers CL may include a semiconductor material. For example, the channel layers CL may be formed of or include silicon or germanium.

Each channel layer CL may include a first side surface CL_S1 and a second side surface CL_S2, which are parallel to the second direction D2. The first and second side surfaces CL_S1 and CL_S2 of the channel layer CL may be opposite to each other.

The bit line structure BS may include a first side surface BS_S1 and a second side surface BS_S2, which are parallel to the second direction D2. The first and second side surfaces BS_S1 and BS_S2 may be two opposite surfaces of the bit line structure BS.

The first side surface CL_S1 of the channel layer CL and the first side surface BS_S1 of the bit line structure BS may be coplanar with each other. The first side surface CL_S1 of the channel layer CL and the first side surface BS_S1 of the bit line structure BS may be placed on a single straight line (e.g., extending in the third direction D3). The first side surface CL_S1 of the channel layer CL and the first side surface BS_S1 of the bit line structure BS may be connected to each other. For example, an uppermost point of the first side surface BS_S1 may contact a lowermost point of the first side surface CL_S1.

The second side surface CL_S2 of the channel layer CL and the second side surface BS_S2 of the bit line structure BS may be coplanar with each other. The second side surface CL_S2 of the channel layer CL and the second side surface BS_S2 of the bit line structure BS may be placed on a single straight line (e.g., extending in the third direction D3). The second side surface CL_S2 of the channel layer CL and the second side surface BS_S2 of the bit line structure BS may be connected to each other. For example, an uppermost point of the second side surface BS_S2 may contact a lowermost point of the second side surface CL_S2.

In an embodiment, a distance between the first and second side surfaces CL_S1 and CL_S2 of the channel layer CL in the first direction D1 may be substantially equal to a distance between the first and second side surfaces BS_S1 and BS_S2 of the bit line structure BS in the first direction D1. In an embodiment, a width W1 of the channel layer CL in the first direction D1 may be equal to a width W2 of the bit line structure BS in the first direction D1. Moreover, the channel layer CL may be thicker, in the third direction D3, than the bit line structure BS.

The shield spacer SS may include a first side surface SS_S1, which is in contact with a side surface BS_S1 or BS_S2 of the bit line structure BS, and a second side surface SS_S2, which is in contact with a side surface SP_S of the shield pattern SP. An upper portion of the side surface SP_S of the shield pattern SP may be in contact with the second side surface SS_S2 of the shield spacer SS. A lower portion of the side surface SP_S of the shield pattern SP may be in contact with a side surface of the shield insulating layer SI.

Gate structures GS may be provided. The gate structure GS may be provided on the bit line structure BS. The gate structure GS may extend in the first direction D1. The gate structures GS may be arranged to be spaced apart from each other in the second direction D2.

The gate structure GS may include two gate insulating layers GI, two gate electrode layers GE, two lower gate insulating layers LGI, an intervening gate insulating layer IGI, and a gate capping layer GP.

The two gate electrode layers GE, the two lower gate insulating layers LGI, and the intervening gate insulating layer IGI may be disposed between the two gate insulating layers GI. The intervening gate insulating layer IGI may be disposed between the two gate electrode layers GE and between the two lower gate insulating layers LGI.

The gate insulating layer GI, the lower gate insulating layer LGI, and the intervening gate insulating layer IGI may be provided on the bit line structure BS. The gate electrode layer GE may be provided on the lower gate insulating layer LGI. The gate capping layer GP may be provided on the gate insulating layer GI, the gate electrode layer GE, and the intervening gate insulating layer IGI. The gate insulating layer GI may be in contact with the side surface CL_S1 or CL_S2 of the channel layer CL, the side surface of the gate electrode layer GE, and the side surface of the lower gate insulating layer LGI. A bottom surface of the gate insulating layer GI may be in contact with a top surface of the shield spacer SS. A bottom surface of the lower gate insulating layer LGI may be in contact with a top surface of the shield pattern SP.

The gate electrode layer GE may include a conductive material. Each of the gate insulating layer GI, the lower gate insulating layer LGI, the intervening gate insulating layer IGI, and the gate capping layer GP may include an insulating material.

Back-gate structures BGS may be provided. The back-gate structures BGS may be provided on the bit line structure BS. The back-gate structures BGS and the gate structures GS may be alternately arranged in the second direction D2. Each back-gate structure BGS may include two back-gate spacers BSP, a lower back-gate insulating layer BGI1, a back-gate electrode layer BGE, and an upper back-gate insulating layer BGI2.

The lower back-gate insulating layer BGI1, the back-gate electrode layer BGE, and the upper back-gate insulating layer BGI2 may be provided between the two back-gate spacers BSP. The back-gate spacer BSP and the lower back-gate insulating layer BGI1 may be provided on the bit line structure BS. The back-gate electrode layer BGE may be provided on the lower back-gate insulating layer BGI1. The upper back-gate insulating layer BGI2 may be provided on the back-gate electrode layer BGE.

The back-gate electrode layer BGE may include a conductive material. Each of the back-gate spacer BSP, the lower back-gate insulating layer BGI1, and the upper back-gate insulating layer BGI2 may include an insulating material.

Pad structures PA and insulating patterns IP may be provided. The pad structure PA may be provided on the gate structure GS, the channel layer CL, and the back-gate structure BGS. The insulating pattern IP may be provided between the pad structures PA. The pad structures PA may be spaced apart from each other by the insulating pattern IP. The pad structure PA may include a conductive material. In an embodiment, the pad structure PA may include a plurality of conductive layers. The insulating pattern IP may include an insulating material. In an embodiment, the insulating pattern IP may include a plurality of insulating layers.

A data storage structure DA may be provided on the pad structure PA and the insulating pattern IP. The data storage structure DA may be electrically connected to the channel layer CL through the pad structure PA. In an embodiment, the data storage structure DA may be a capacitor. In this case, the data storage structure DA may include a bottom electrode, a top electrode, and a capacitor dielectric layer interposed therebetween. In an embodiment, the data storage structure DA may be a variable resistance pattern whose resistance can be switched to one of at least two states by an electric pulse applied thereto. For example, the data storage structure DA may be formed of or include at least one of phase-change materials whose crystal state can be changed depending on an amount of a current applied thereto, perovskite compounds, transition metal oxides, magnetic materials, ferromagnetic materials, or antiferromagnetic materials.

A second interlayer insulating layer 150 may be provided on the first interlayer insulating layer 140 and the bit line structure BS. The second insulating layer 150 may include an insulating material. In an embodiment, the second interlayer insulating layer 150 may have a multi-layer structure including a plurality of insulating layers.

A second gate connection contact GC2, a third gate connection contact GC3, and a gate connection line GL may be provided. The second gate connection contact GC2 may extend in the third direction D3 in (e.g., to pass through) the first and second interlayer insulating layers 140 and 150. A bottom surface of the second gate connection contact GC2 may be in contact with the top surface of the gate connection pad GA. The third gate connection contact GC3 may extend in the third direction D3 in (e.g., to pass through) the gate capping layer GP and the second interlayer insulating layer 150. A bottom surface of the third gate connection contact GC3 may be in contact with a top surface of the gate electrode layer GE. A bottom surface of the gate connection line GL may be in contact with a top surface of the second gate connection contact GC2 and a top surface of the third gate connection contact GC3.

The gate electrode layer GE of the gate structure GS may be electrically connected to the gate connection pad GA through the third gate connection contact GC3, the gate connection line GL, and the second gate connection contact GC2. Each of the third gate connection contact GC3, the gate connection line GL, and the second gate connection contact GC2 may include a conductive material.

In the semiconductor device according to an embodiment of the inventive concept, since the bit line connection contact BO is directly bonded to (i.e., in contact with) the bit line structure BS, it may be possible to omit additional interconnection lines, which are used to electrically connect the bit line structure BS to the bit line connection contact BO. This may make it possible to improve a degree of freedom in designing the semiconductor device, to simplify a process of fabricating the semiconductor device, and to reduce the size of the semiconductor device.

In the semiconductor device according to an embodiment of the inventive concept, since the gate connection pad GA is disposed on the shield insulating layer SI, it may be possible to electrically connect the gate connection pad GA to the gate structure GS with relatively little difficulty and to reduce the size of the gate connection pad GA.

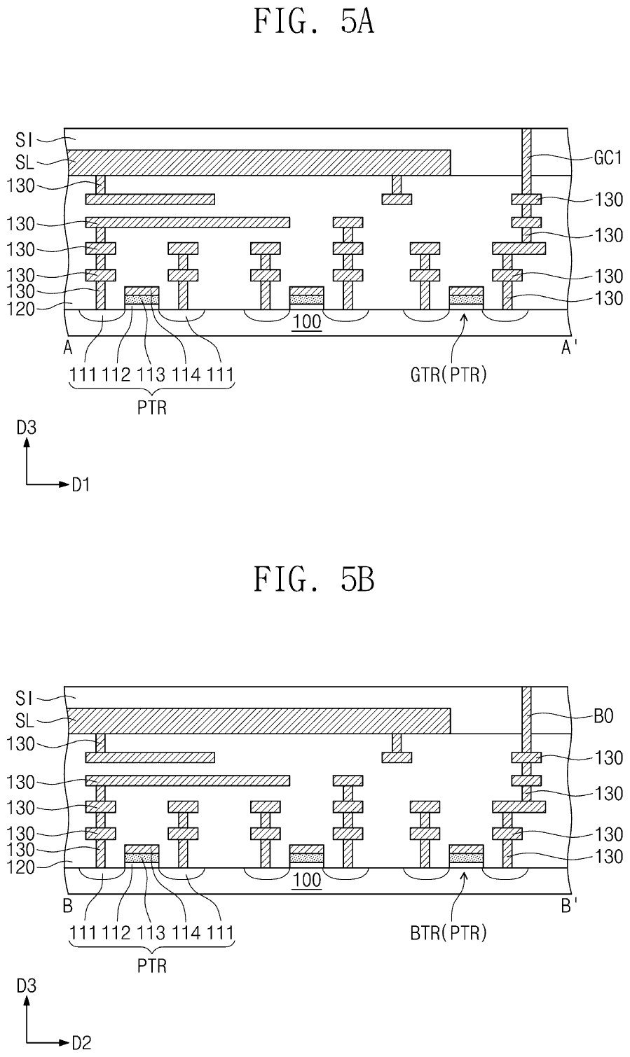

FIGS. 5A, 5B, 6A, 6B, 7A, 7B, 8A, 8B, and 9 are sectional views illustrating a method of fabricating a semiconductor device according to an embodiment of the inventive concept.

Referring to FIGS. 5A and 5B, the peripheral transistors PTR may be formed on the substrate 100. The peripheral circuit insulating layer 120 may be formed on the substrate 100. The peripheral conductive structures 130 may be formed in the peripheral circuit insulating layer 120.

The shield layer SL may be formed on the peripheral circuit insulating layer 120. The shield insulating layer SI may be formed on the shield layer SL. The first gate connection contact GC1 and the bit line connection contact BO may be formed. The formation of the first gate connection contact GC1 and the bit line connection contact BO may include forming holes in (e.g., to penetrate) the shield insulating layer SI and forming the first gate connection contact GC1 and the bit line connection contact BO in the holes. The top surface of the first gate connection contact GC1 and the top surface of the bit line connection contact BO may be exposed to the outside of the shield insulating layer SI near the top surface of the shield insulating layer SI.

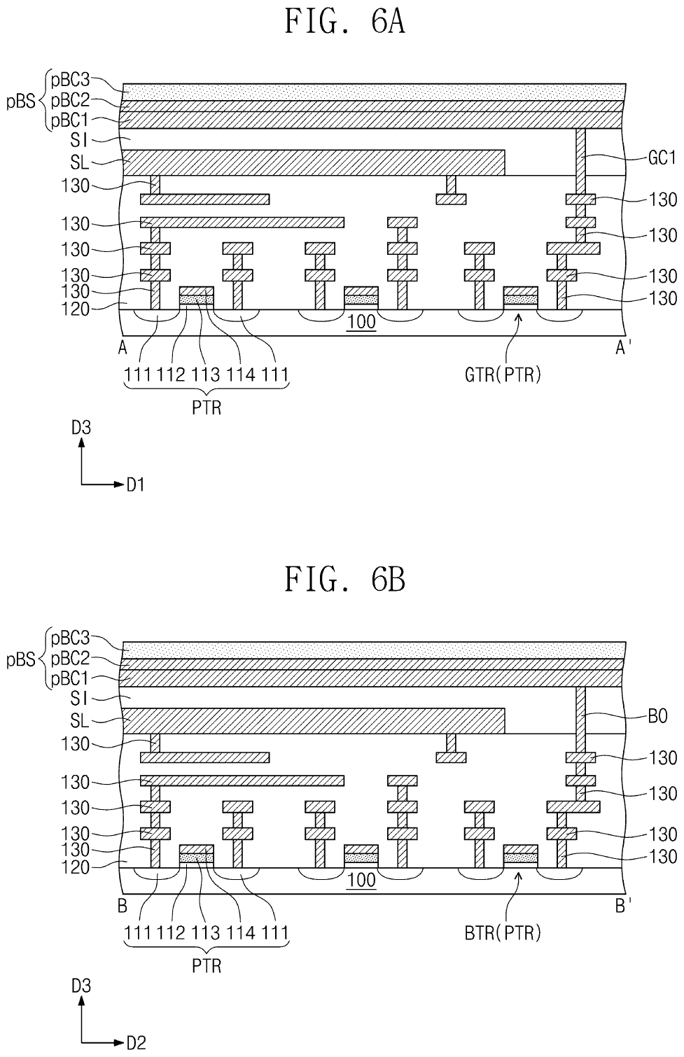

Referring to FIGS. 6A and 6B, a preliminary bit line structure pBS may be formed. The preliminary bit line structure pBS may include a first preliminary bit line layer pBC1, a second preliminary bit line layer pBC2 on the first preliminary bit line layer pBC1, and a third preliminary bit line layer pBC3 on the second preliminary bit line layer pBC2. The first to third preliminary bit line layers pBC1, pBC2, and pBC3 may be sequentially formed through a deposition process.

A bottom surface of the first preliminary bit line layer pBC1 of the preliminary bit line structure pBS may be in contact with the top surface of the first gate connection contact GC1, the top surface of the bit line connection contact BO, and the top surface of the shield insulating layer SI.

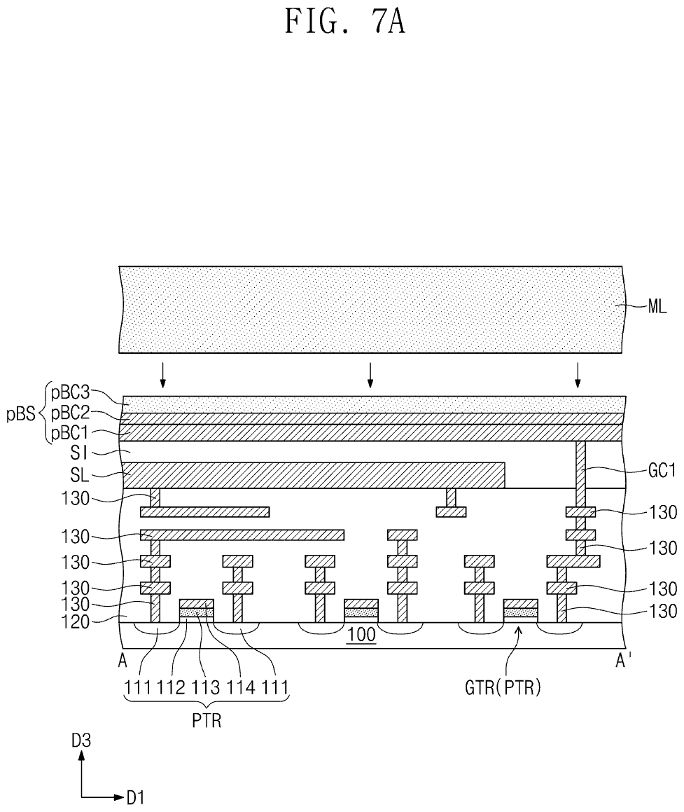

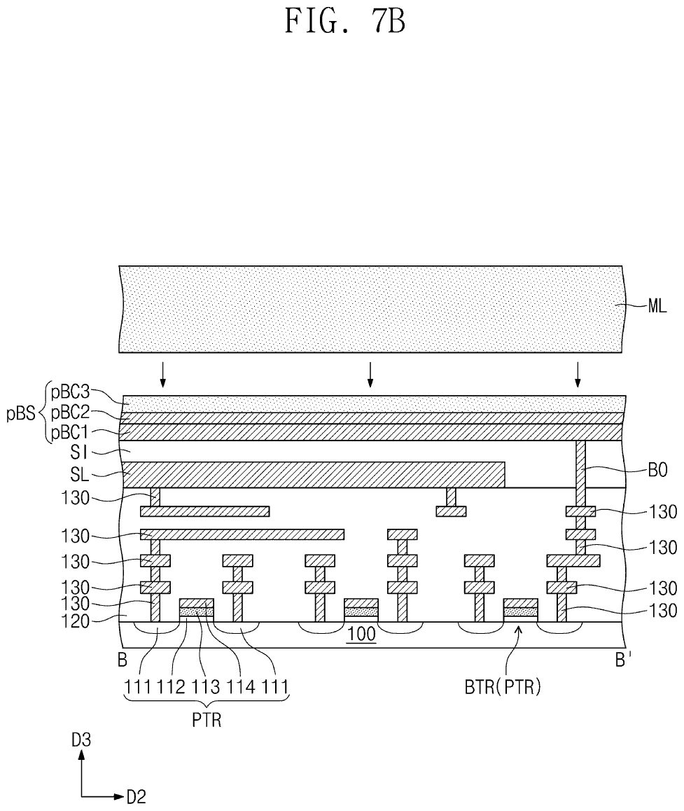

Referring to FIGS. 7A and 7B, a material layer ML may be formed on the preliminary bit line structure pBS. The material layer ML may be bonded to the third preliminary bit line layer pBC3 of the preliminary bit line structure pBS through a wafer bonding process. The material layer ML may be a semiconductor substrate. For example, the material layer ML may be a silicon substrate or a germanium substrate.

In an embodiment, the material layer ML may be formed on the third preliminary bit line layer pBC3 of the preliminary bit line structure pBS through a deposition process.

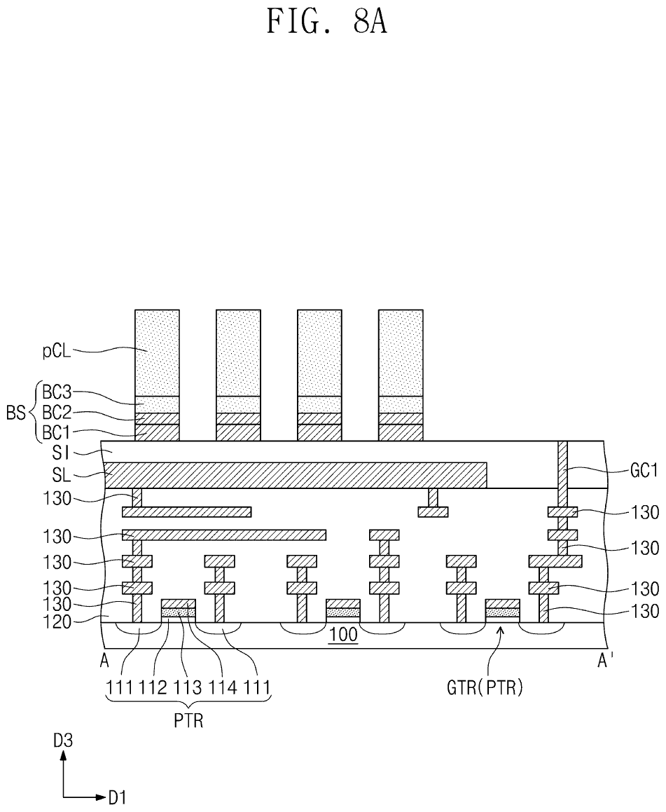

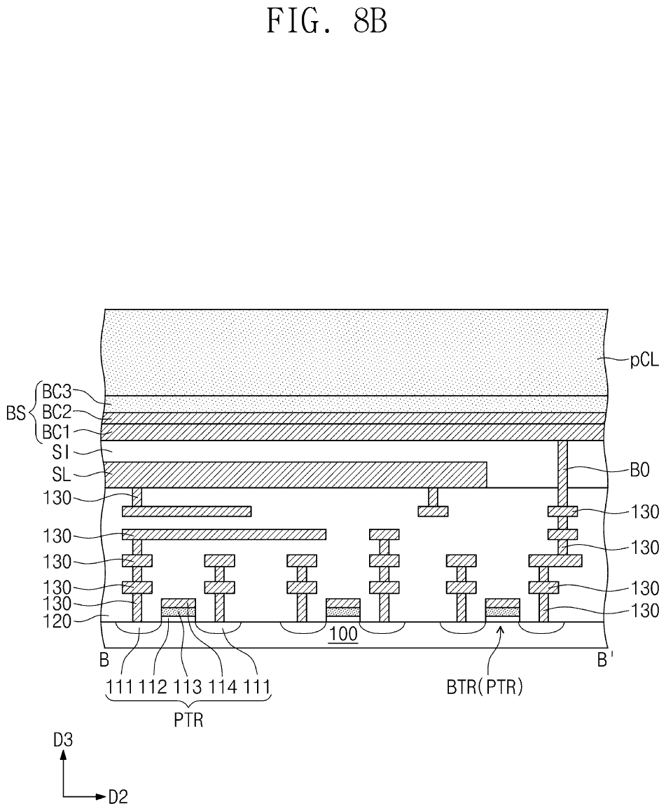

Referring to FIGS. 8A and 8B, the material layer ML and the preliminary bit line structure pBS may be patterned. As a result of the patterning step, the material layer ML may form preliminary channel layers pCL, which are separated from each other. Similarly, the preliminary bit line structure pBS may form bit line structures BS, which are separated from each other. The preliminary channel layers pCL may extend in the second direction D2.

In an embodiment, the patterning of the material layer ML and the preliminary bit line structure pBS may include forming a mask pattern on the material layer ML and patterning the material layer ML and the preliminary bit line structure pBS using the mask pattern as an etch mask.

In an embodiment, the patterning of the material layer ML and the preliminary bit line structure pBS may include forming a mask pattern on the material layer ML, patterning the material layer ML using the mask pattern as an etch mask to form the preliminary channel layer pCL, and patterning the preliminary bit line structure pBS using the preliminary channel layer pCL as an etch mask.

A side surface of the preliminary channel layer pCL may be coplanar with the side surface of the bit line structure BS. In an embodiment, a width of the preliminary channel layer pCL in the first direction D1 may be equal to a width of the bit line structure BS in the first direction D1.

As a result of the patterning of the preliminary bit line structure pBS, the top surface of the first gate connection contact GC1 may be exposed to the outside.

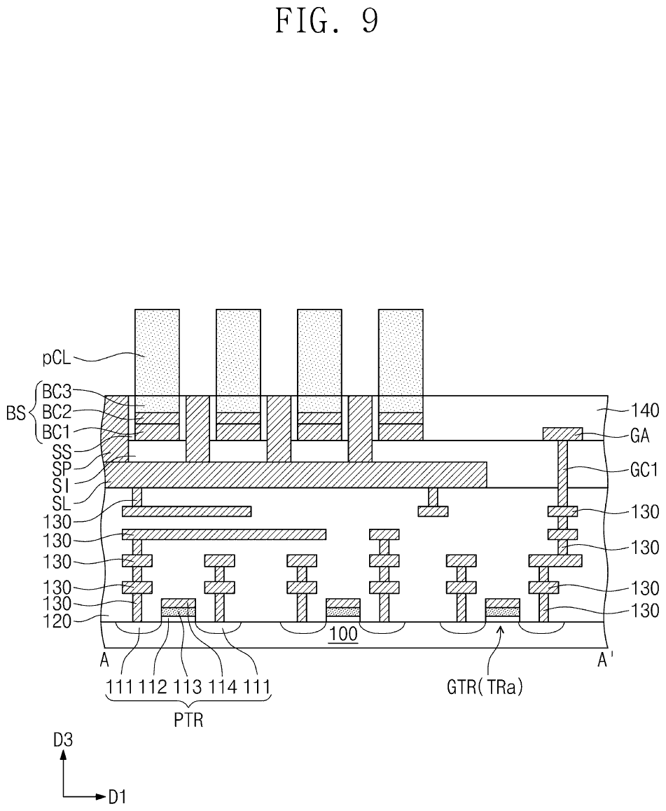

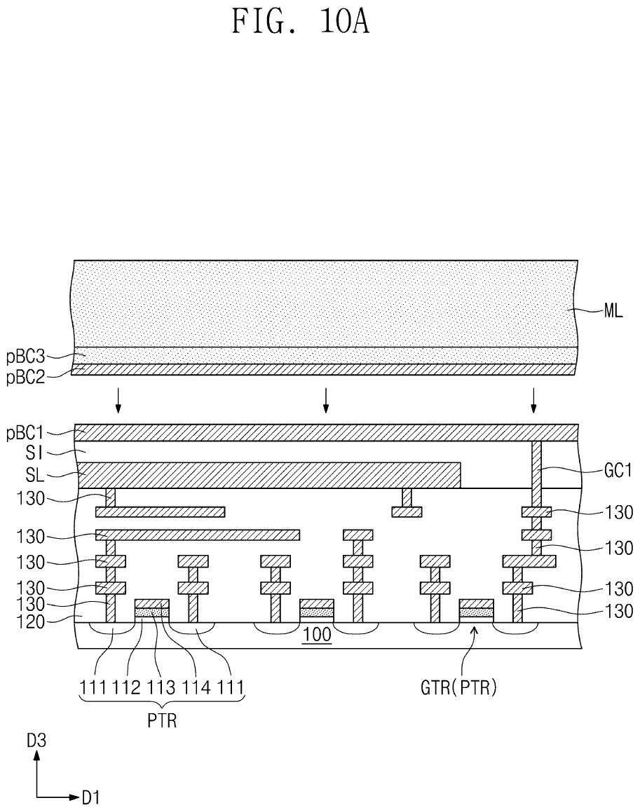

Referring to FIG. 9, the shield pattern SP and the shield spacer SS may be formed. The formation of the shield pattern SP and the shield spacer SS may include conformally forming a shield spacer layer on side surfaces of the bit line structures BS and the top surface of the shield insulating layer SI, forming a trench in (e.g., to penetrate) the shield spacer layer and the shield insulating layer SI, and forming the shield pattern SP in the trench. As a result of the formation of the trench, the shield spacer layer may be divided into two shield spacers SS.

The gate connection pad GA may be formed on the first gate connection contact GC1. The first interlayer insulating layer 140 may be formed on the gate connection pad GA.

Referring to FIGS. 4A to 4D, the preliminary channel layer pCL may be patterned. As a result, the preliminary channel layer pCL may form the channel layers CL, which are separated from each other. Furthermore, the back-gate structures BGS and the gate structures GS may be formed. Thereafter, the pad structures PA, the insulating patterns IP, and the data storage structure DA may be formed. The second interlayer insulating layer 150 may be formed on the first interlayer insulating layer 140. In addition, the second gate connection contact GC2, the third gate connection contact GC3, and the gate connection line GL may be formed.

In the fabrication method according to an embodiment of the inventive concept, the preliminary bit line structure pBS and the material layer ML may be formed on the shield insulating layer SI, and then, the channel layer CL and the bit line structure BS may be formed by patterning the material layer ML and the preliminary bit line structure pBS. Since the wafer bonding process is not performed after the formation of the channel layer CL and the bit line structure BS, there may be no need to form a relatively large pad to reduce a misalignment issue, which may be caused by the wafer bonding process, and it may be possible to reduce the size of the gate connection pad GA. Thus, it may be possible to reduce the size of the semiconductor device.

In the fabrication method according to an embodiment of the inventive concept, since the bit line structure BS is formed on the bit line connection contact BO through a deposition process, it may be possible to omit additional interconnection liens for connecting the bit line structure BS to the bit line connection contact BO. Accordingly, it may be possible to improve a degree of freedom in designing a semiconductor device and to reduce a size of the semiconductor device.

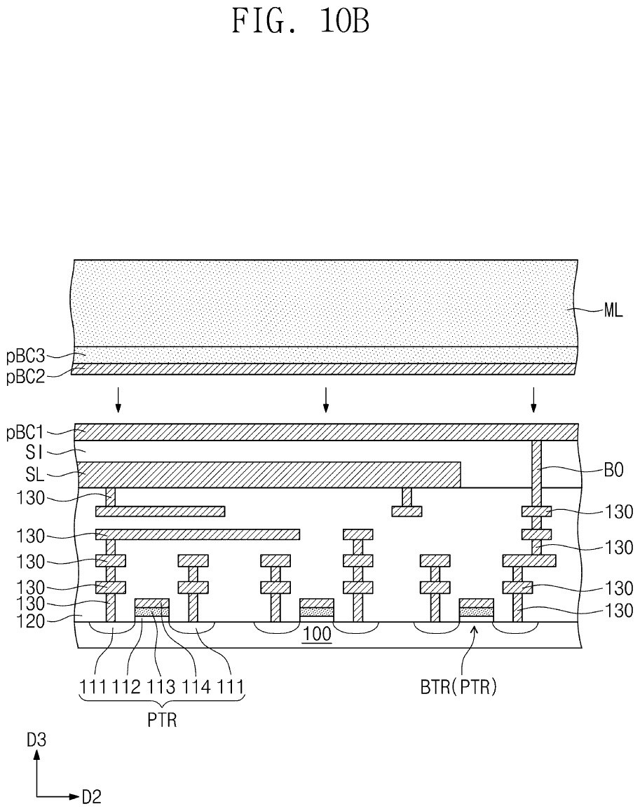

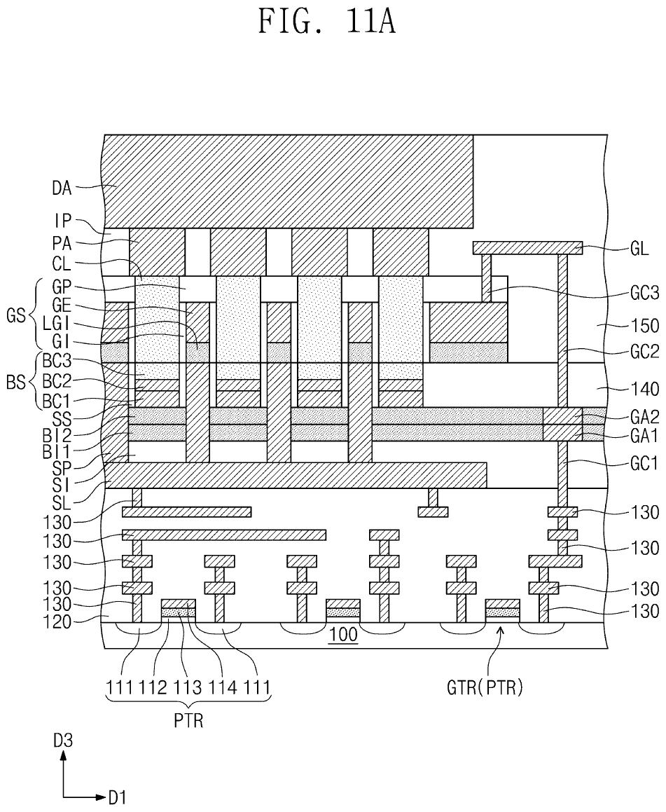

FIGS. 10A and 10B are sectional views illustrating a method of fabricating a semiconductor device according to an embodiment of the inventive concept.

Referring to FIGS. 10A and 10B, the shield layer SL, the shield insulating layer SI, the first gate connection contact GC1, and the bit line connection contact BO may be formed, similar to the embodiment of FIGS. 5A and 5B.

The first preliminary bit line layer pBC1 may be formed on the shield insulating layer SI, the first gate connection contact GC1, and the bit line connection contact BO. The first preliminary bit line layer pBC1 may be formed through a deposition process.

The third preliminary bit line layer pBC3 may be formed on the material layer ML, and the second preliminary bit line layer pBC2 may be formed on the third preliminary bit line layer pBC3. The third preliminary bit line layer pBC3 and the second preliminary bit line layer pBC2 may be formed through a deposition process.

A wafer bonding process may be performed to bond the second preliminary bit line layer pBC2 to the first preliminary bit line layer pBC1.

Thereafter, the remaining subsequent processes may be performed in a similar manner to those in the embodiment of FIGS. 8A, 8B, 9, 4A, 4B, 4C, and 4D.

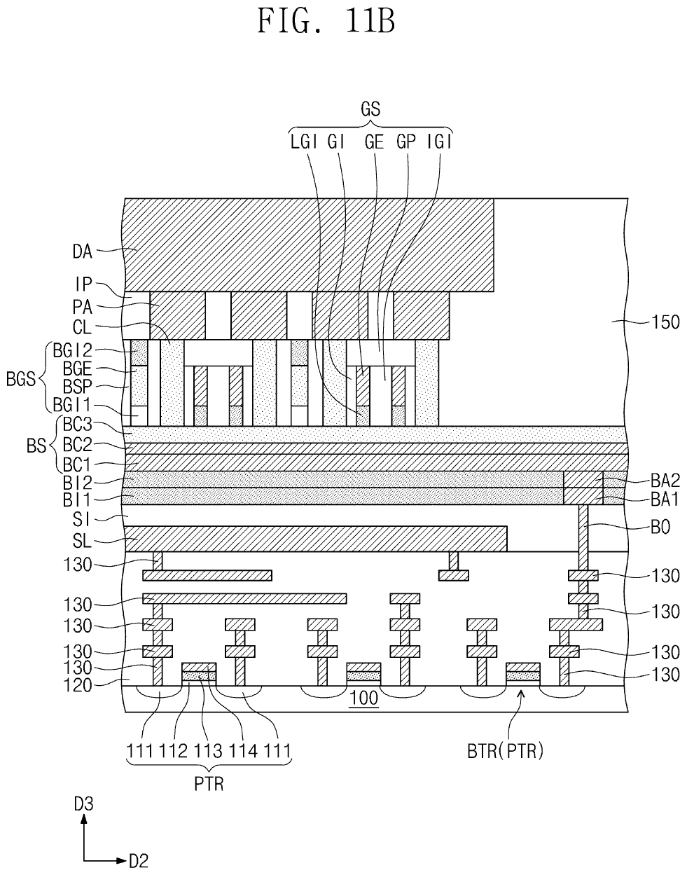

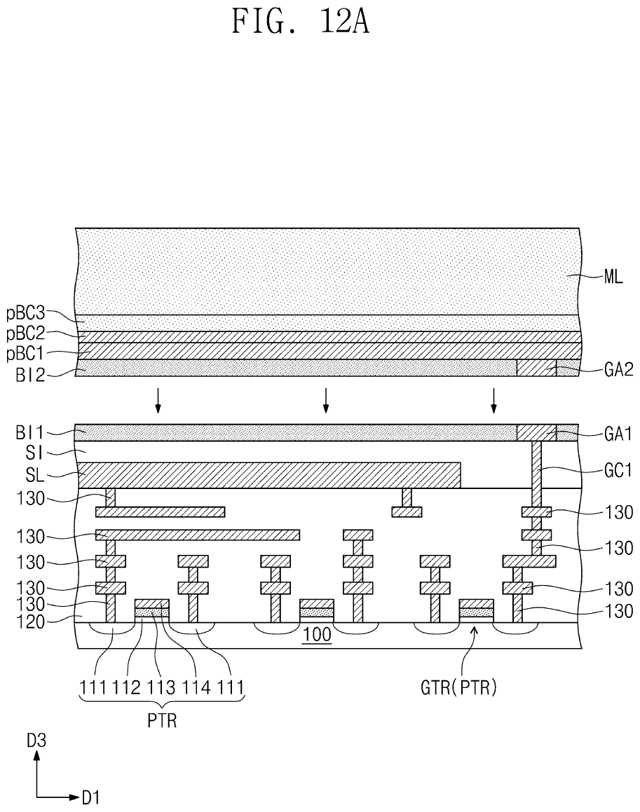

FIGS. 11A and 11B are sectional views illustrating a semiconductor device according to an embodiment of the inventive concept. The semiconductor device of FIGS. 11A and 11B may have similar features to the semiconductor device of FIGS. 4A to 4D, except for the features to be described below.

Referring to FIGS. 11A and 11B, a first bonding insulating layer BI1 may be provided on the shield insulating layer SI. A second bonding insulating layer BI2 may be provided on the first bonding insulating layer BI1. The bit line structures BS and the first interlayer insulating layer 140 may be provided on the second bonding insulating layer BI2. The shield pattern SP may be in (e.g., may penetrate) the second bonding insulating layer BI2, the first bonding insulating layer BI1, and the shield insulating layer SI. A bottom surface of the shield spacer SS may be in contact with a top surface of the second bonding insulating layer BI2. Each of the first and second bonding insulating layers BI1 and BI2 may include an insulating material.

A first gate connection pad GA1 and a first bit line connection pad BA1 may be provided in the first bonding insulating layer BI1. A second gate connection pad GA2 and a second bit line connection pad BA2 may be provided in the second bonding insulating layer BI2.

A bottom surface of the first gate connection pad GA1 may be in contact with the top surface of the first gate connection contact GC1. A top surface of the first gate connection pad GA1 may be in contact with a bottom surface of the second gate connection pad GA2. A top surface of the second gate connection pad GA2 may be in contact with the bottom surface of the second gate connection contact GC2.

The gate electrode layer GE of the gate structure GS may be electrically connected to the gate connection transistor GTR through the third gate connection contact GC3, the gate connection line GL, the second gate connection contact GC2, the second gate connection pad GA2, the first gate connection pad GA1, the first gate connection contact GC1, and the peripheral conductive structures 130.

A bottom surface of the first bit line connection pad BA1 may be in contact with the top surface of the bit line connection contact BO. A top surface of the first bit line connection pad BA1 may be in contact with a bottom surface of the second bit line connection pad BA2. A top surface of the second bit line connection pad BA2 may be in contact with a bottom surface of the first bit line layer BC1 of the bit line structure BS.

The bit line structure BS may be electrically connected to the bit line connection transistor BTR through the second bit line connection pad BA2, the first bit line connection pad BA1, the bit line connection contact BO, and the peripheral conductive structures 130.

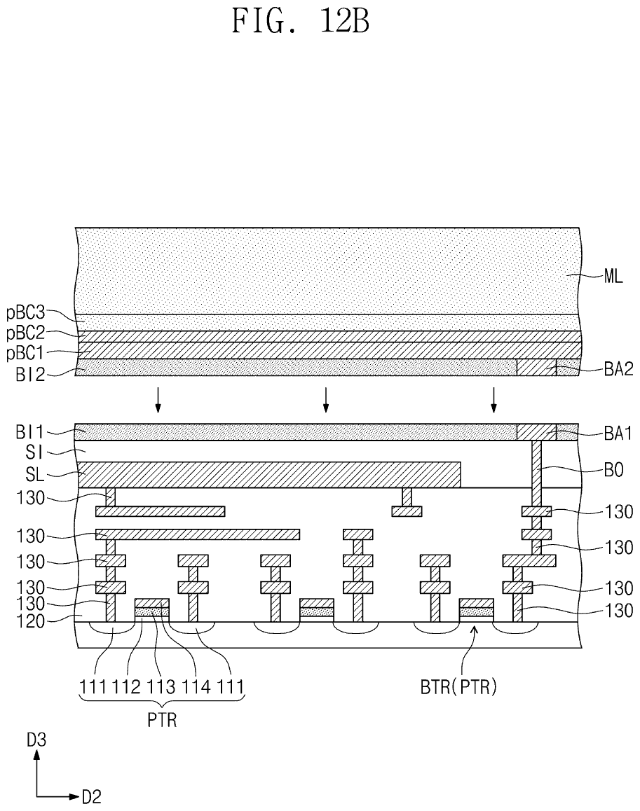

FIGS. 12A and 12B are sectional views illustrating a method of fabricating a semiconductor device according to an embodiment of the inventive concept.

Referring to FIGS. 12A and 12B, the shield layer SL, the shield insulating layer SI, the first gate connection contact GC1, and the bit line connection contact BO may be formed, similar to the embodiment of FIGS. 5A and 5B.

The first bonding insulating layer BI1 may be formed on the shield insulating layer SI. The first bonding insulating layer BI1 may be formed through a deposition process. The first gate connection pad GA1 and the first bit line connection pad BA1 may be formed in the first bonding insulating layer BI1.

The third preliminary bit line layer pBC3 may be formed on the material layer ML. The second preliminary bit line layer pBC2 may be formed on the third preliminary bit line layer pBC3. The first preliminary bit line layer pBC1 may be formed on the second preliminary bit line layer pBC2. The second bonding insulating layer BI2 may be formed on the first preliminary bit line layer pBC1. The first to third preliminary bit line layers pBC1, pBC2, and pBC3 and the second bonding insulating layer BI2 may be formed through a deposition process.

The second gate connection pad GA2 and the second bit line connection pad BA2 may be formed in the second bonding insulating layer BI2.

A hybrid wafer bonding process may be performed. As a result of the wafer bonding process, the first bonding insulating layer BI1 may be bonded to the second bonding insulating layer BI2. The first gate connection pad GA1 may be bonded to the second gate connection pad GA2 through the wafer bonding process. The first bit line connection pad BA1 may be bonded to the second bit line connection pad BA2 through the wafer bonding process.

In a semiconductor device according to an embodiment of the inventive concept, since a bit line structure is directly bonded to a bit line connection contact, it may be possible to omit additional interconnection lines, which are used to electrically connect the bit line structure to the bit line connection contact.

In a method of fabricating a semiconductor device according to an embodiment of the inventive concept, since a wafer bonding process is not performed after forming a channel layer and a bit line structure, there is no need to form a relatively large pad to reduce a misalignment issue caused by the wafer bonding process, and it may be possible to reduce a size of a gate connection pad.

While example embodiments of the inventive concept have been particularly shown and described, it will be understood by one of ordinary skill in the art that variations in form and detail may be made therein without departing from the scope of the attached claims.

1. A semiconductor device comprising:
a bit line structure extending in a first direction;
a channel layer on the bit line structure;
a gate structure on the bit line structure and extending in a second direction crossing the first direction; and
a data storage structure electrically connected to the channel layer,
wherein the bit line structure comprises a first side surface and a second side surface that are parallel to the first direction,
wherein the channel layer comprises a first side surface and a second side surface that are parallel to the first direction,
wherein the first side surface of the bit line structure is coplanar with the first side surface of the channel layer, and
wherein the second side surface of the bit line structure is coplanar with the second side surface of the channel layer.

2. The semiconductor device of claim 1,
wherein a width of the bit line structure in the second direction is equal to a width of the channel layer in the second direction, and
wherein the channel layer is thicker, in a vertical direction, than the bit line structure.

3. The semiconductor device of claim 1, further comprising:
a shield pattern spaced apart from the bit line structure in the second direction;
a shield spacer that is between, in the second direction, the bit line structure and the shield pattern, wherein the shield spacer is in contact with a side surface of the shield pattern and the first side surface of the bit line structure; and
a shield layer in contact with a bottom surface of the shield pattern,
wherein the bit line structure overlaps the shield layer in a vertical direction.

4. The semiconductor device of claim 3, wherein the gate structure comprises:
a lower gate insulating layer on the shield pattern;
a gate electrode layer on the lower gate insulating layer; and
a gate insulating layer in contact with a side surface of the gate electrode layer and the first side surface of the channel layer.

5. The semiconductor device of claim 1, further comprising:
a shield insulating layer in contact with a bottom surface of the bit line structure; and
a bit line connection contact in the shield insulating layer,
wherein a top surface of the bit line connection contact is in contact with the bottom surface of the bit line structure.

6. The semiconductor device of claim 5, further comprising:
a substrate;
a bit line connection transistor on the substrate; and
a peripheral conductive structure that is electrically connected to the bit line connection transistor,
wherein the bit line connection contact is electrically connected to the bit line connection transistor through the peripheral conductive structure, and
wherein a bottom surface of the bit line connection contact is in contact with the peripheral conductive structure.

7. The semiconductor device of claim 1, further comprising:
a substrate;
a gate connection transistor on the substrate; and
a gate connection pad electrically connecting the gate connection transistor to the gate structure,
wherein a bottom surface of the gate connection pad is coplanar with a bottom surface of the bit line structure.

8. The semiconductor device of claim 7, further comprising:
a shield layer; and
a shield insulating layer on the shield layer,
wherein a top surface of the shield insulating layer is in contact with the bottom surface of the bit line structure and the bottom surface of the gate connection pad, and
wherein a top surface of the gate connection pad is at a lower level than a top surface of the bit line structure.

9. A semiconductor device comprising:
a gate connection transistor;
a shield layer at a level higher than the gate connection transistor;
a shield insulating layer on the shield layer;
a gate connection contact in the shield insulating layer;
bit line structures on a top surface of the shield insulating layer;
a gate connection pad on the top surface of the shield insulating layer and a top surface of the gate connection contact; and
gate structures on the bit line structures,
wherein one of the gate structures is electrically connected to the gate connection transistor through the gate connection pad and the gate connection contact.

10. The semiconductor device of claim 9, wherein a bottom surface of the gate connection pad is coplanar with a bottom surface of each of the bit line structures.

11. The semiconductor device of claim 9, wherein the top surface of the gate connection contact is coplanar with the top surface of the shield insulating layer.

12. The semiconductor device of claim 9, further comprising an interlayer insulating layer on the shield insulating layer,
wherein the interlayer insulating layer is in contact with a side surface of the gate connection pad and a side surface of one of the bit line structures.

13. The semiconductor device of claim 9, further comprising:
shield spacers between, in a horizontal direction, the bit line structures; and
a shield pattern between, in the horizontal direction, the shield spacers,
wherein a bottom surface of each of the shield spacers is in contact with the top surface of the shield insulating layer.

14. The semiconductor device of claim 9, wherein a level of a top surface of the gate connection pad is lower than a level of a top surface of each of the bit line structures.

15. The semiconductor device of claim 9, further comprising:
a bit line connection contact in contact with a bottom surface of one of the bit line structures; and
a bit line connection transistor electrically connected to the bit line connection contact,
wherein the bit line connection contact extends in the shield insulating layer.

16. A semiconductor device comprising:
a substrate;
a bit line connection transistor on the substrate;
a gate connection transistor on the substrate;
a peripheral circuit insulating layer on the substrate;
a shield layer on the peripheral circuit insulating layer;
a shield insulating layer on the shield layer;
a bit line structure on the shield insulating layer;
a gate connection pad on the shield insulating layer;
a first gate connection contact extending in the shield insulating layer;
a bit line connection contact extending in the shield insulating layer;
a gate structure on the bit line structure;
a channel layer on the bit line structure;
a pad structure on the channel layer; and
a data storage structure electrically connected to the pad structure,
wherein the gate structure is electrically connected to the gate connection transistor through the gate connection pad and the first gate connection contact, and
wherein the bit line structure is electrically connected to the bit line connection transistor through the bit line connection contact.

17. The semiconductor device of claim 16, wherein a width of the channel layer is equal to a width of the bit line structure.

18. The semiconductor device of claim 16,
wherein the bit line structure comprises a first portion that overlaps the shield layer in a vertical direction, and a second portion that does not overlap the shield layer in the vertical direction, and
wherein the bit line connection contact is in contact with the second portion of the bit line structure.

19. The semiconductor device of claim 16, further comprising a second gate connection contact in contact with a top surface of the gate connection pad,
wherein a level of a bottom surface of the second gate connection contact is higher than a level of a bottom surface of the bit line structure.

20. The semiconductor device of claim 16, further comprising:
a shield pattern in contact with the shield layer and the gate structure; and
shield spacers on opposite side surfaces of the shield pattern.

21.-28. (canceled)
